(19) United States
(12) Patent Application Publication
(10) Pub. No.: US 2014/0326306 A1
(43) Pub. Date: Nov. 6, 2014

(54) HIGHLY EFFICIENT SOLAR CELL MODULE

(71) Applicant: Changzhou Almaden Co., Ltd., Changzhou (CN)

(72) Inventors: JINXI LIN, Changzhou (CN); Jinhan Lin, Changzhou (CN); Yuting Lin, Wufeng Township (TW); Chun Liang Lin, New Taipei City (TW)

(73) Assignee: Changzhou Almaden Co., Ltd., Changzhou (CN)

(21) Appl. No.: 14/268,665

(22) Filed: May 2, 2014

(30) Foreign Application Priority Data
May 3, 2013 (TW) 201310163811.9

(51) Int. Cl. H01L 31/048

(52) U.S. Cl. CPC H01L 31/0488
USPC 136/256

(57) ABSTRACT

The subject invention discloses a solar cell module comprising: a first glass layer, wherein one side of the glass layer comprises embossing, the surface angle of the embossing is in the range of 1 to 45 degrees, and the surface of the embossing comprises a reflective coating; a first encapsulated layer located above the first glass layer; a bifacial solar cell located above the first encapsulated layer; a second encapsulated layer located above the bifacial solar cell; and a second glass layer located above the second encapsulated layer.

### BACKGROUND OF THE INVENTION

1. Field of the Invention

The present invention is directed to a highly efficient solar cell module, and particularly to a highly efficient bifacial solar cell module.

2. Description of the Related Art

Solar energy is the most prevalently used source of environmentally friendly energy. Generally, solar energy is converted into electric energy by utilizing the photovoltaic effect of solar cells. Solar cells are environmentally friendly and energy efficient, and have been gaining ground in daily applications.

A solar cell module is generally formed by combining a multilayered structure of glass, ethylene vinyl acetate (EVA), solar cell panels (solar cell panels with a size of 5 inches or 6 inches generally put together to form a larger area) and a solar energy back sheet, in addition to peripheral components such as outer frame made of aluminum, galvanized steel sheet, wood and synthetic materials (such as polyethylene (PE), polypropylene (PP) and ethylene-propylene rubber), a junction box, lead wires, and a battery. Under sunlight irradiation, the solar cell module outputs a certain working voltage and working current through photovoltaic effect.

A solar cell module with a large area is formed by putting together solar cells having a small area. To avoid overlap of solar cells (that is, one solar cell on top of another) in the lamination process of the preparation of the solar cell module, gaps are usually kept between solar cells. The gaps are about 2 to 5% of the total area of the solar cell module. However, overly large gaps result in a portion of light passing through the solar cell module not passing through the solar cells. Thus, the overall efficiency of the solar cell module is lower than that of the individual solar cell and the solar cell module generates less power than expected.

To solve the above-mentioned technical problem, the subject application provides a highly efficient solar cell module.

### SUMMARY OF THE INVENTION

One object of the subject invention is to provide a solar cell module, comprising:
a first glass layer, wherein one side of the glass layer comprises embossing, the surface angle of the embossing is in the range of 1 to 45 degrees, and the surface of the embossing comprises a light reflective coating;
a first encapsulated layer located above the first glass layer;
a bifacial solar cell located above the first encapsulated layer;
a second encapsulated layer located above the bifacial solar cell; and
a second glass layer located above the second encapsulated layer.

### BRIEF DESCRIPTION OF THE DRAWINGS

FIG. 1A and FIG. 1B show a cross-section view of a solar cell module of the concrete embodiment of the subject invention.

### PREFERRED EMBODIMENTS OF THE PRESENT INVENTION

In this context, unless otherwise limited, a singular term (such as “a”) also includes the plural form thereof. In this context, all embodiments and exemplary terms (for example, “such as”) only aim at making the present invention more clearly understood, but are not intended to limit the scope of the present invention; terms in this specification should not be construed as implying that any component not claimed may form a necessary component for implementing the present invention.

The subject invention provides a solar cell module, comprising: a first glass layer, wherein one side of the glass layer comprises embossing, the surface angle of the embossing is in the range of 1 to 45 degrees, and the surface of the embossing comprises a light reflective coating; a first encapsulated layer located above the first glass layer; a bifacial solar cell located above the first encapsulated layer; a second encapsulated layer located above the bifacial solar cell; and a second glass layer located above the second encapsulated layer.

The following paragraphs are directed to further explanations for each part of the solar cell module and technical features of the subject invention.

In the subject invention, not only is the light incident side of the solar cell module a glass layer (a second glass layer), but the back sheet of the solar cell module may also use a glass layer (a first glass layer). The first glass layer or the second glass layer of the present invention preferably has a thickness from about 0.5 mm to about 3 mm. The glass used in the glass layer of the subject invention is preferably tempered glass. The tempered glass can be a novel type of physical tempered glass, which may be made through treatment procedures such as aerodynamic heating and cooling. Specifically, this physical tempered glass may be made by performing heating in an aerodynamic-heating tempering furnace (such as a flatbed tempering furnace produced by LiSEC Corporation) at a temperature ranging from about 600° C. to about 750° C., preferably from about 630° C. to about 700° C., and then performing rapid cooling through, for example, an air nozzle. In this context, the term “aerodynamic heating” refers to a process of transferring heat to an object through high-temperature gas generated when the object and air or other gases move at a high relative velocity or a process of transferring heat to an object through gas flotation principle to replace conventional direct-contact manner when the object passes through the heating furnace or tempering furnace. When the tempered glass is heated in the aerodynamic heating manner, the glass and the tempering furnace do not directly contact, so the glass is not deformed, and is suitable for thin glass. For a more detailed physical tempered glass preparation method, reference may be made to the content of Chinese Patent Application No. 201110198526.1 (corresponding to U.S. patent application Ser. No. 13/541,995). The tempered glass suitable for the present invention is transparent ultrathin tempered glass with a thickness preferably of 0.5 mm to 2.5 mm. The physical tempered glass suitable for the present invention should have a compressive strength of about 120 MPa to about 300 MPa, preferably about 150 MPa to about 250 MPa, a bending strength of about 120 MPa to about 300 MPa, preferably about 150 MPa to about 250 MPa, and a tensile strength of about 90 MPa to about 180 MPa, preferably about 100 MPa to about 150 Mpa.

In the prior art, an embossing glass may be used on the light incident side of the solar cell module. The embossing glass is transparent decorative flat glass with a concave-convex pattern on a single side or double sides which is prepared by special pressing techniques. The embossing glass has a special pattern, such as pyramid, honeycomb, rhombus and so on, on the surface of the glass which is usually pressed by using a tailor-made engraved roller. A special embossing design may reduce direct reflection of light from the glass, increase internal reflection, facilitate absorption of light energy, substantially increase the transmittance of sunlight and enhance the efficiency of power generation. It has outstanding advantages in terms of high sun energy transmittance, low reflection rate, high mechanical strength, high flatness and so on. However, the present invention uses the embossing glass as the back sheet of the solar cell module. Specifically, for the glass layer as the back sheet of the solar cell module, at least one side of such glass layer comprises embossing, the surface angle of the embossing is in the range of 1 to 45 degrees, the depth of the embossing is of 35 μm to 80 μm, and the surface of the embossing comprises a light reflective coating. Suitable materials for the light reflective coating are light-reflecting metals, such as silver, gold, aluminum or chromium, preferably silver or aluminum. The light reflective coating has a thickness from 40 to 200 nm, preferably from 60 to 150 nm. The above-mentioned ranges may include any value in the ranges or any subrange within the ranges. Taking a thickness from about 40 nm to about 70 nm for example, the range of the thickness can include from about 48 nm to about 57 nm, or from about 53 nm to about 65 nm. Other ranges in the subject application are defined in the same manner, i.e., they may include any value in the ranges or any subrange within the ranges.

The object of the light reflective coating is to reflect the light which has passed through the gaps between the solar cells in the solar cell module. Since the embossing has a surface angle, the light which is reflected by the light reflective coating would not pass through the gaps again and be wasted, but be reflected to the solar cells to be converted into electric energy, thereby improving the overall efficiency of the solar cell module. The solar cells in the solar cell module of the present invention are bifacial solar cells, such as HIT Double® of the Japanese corporation Sanyo; such bifacial solar cells can receive reflective light which has passed through gaps and been reflected by the light reflective coating, to make full use of the light energy reflected back to the optoelectronic elements.

The encapsulated layer used in the solar cell module of the present invention is mainly to fix the optoelectronic elements of the solar cell and to provide physical protection for them, for example, impact and moisture resistance. The encapsulated layer in the solar cell module of the present invention can be made of any conventional material, including ethylene vinyl acetate (EVA), polyvinyl butyral (PVB), thin film ionic polymers, such as

Dupont PV5400, and silicone resin, of which ethylene vinyl acetate is presently the most extensively used encapsulated layer material. EVA is a thermosetting resin that offers high transmittance, thermo resistance, thermal insulation (low temperature resistance), moisture resistance, and weather resistance after being cured. In addition, it adheres well to metals, glass and plastics, and has certain elasticity, impact resistance and thermo conductivity. Thus, EVA is an ideal material for the solar cell encapsulated layer.

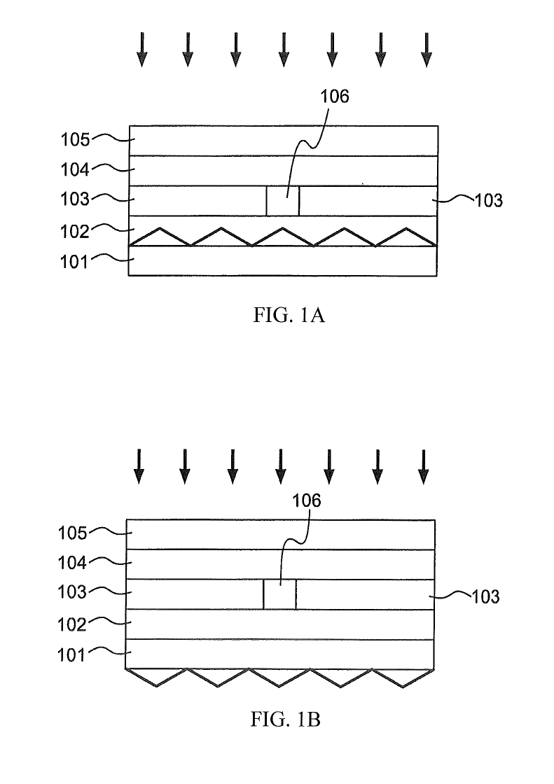

As shown in FIG. 1A or 1B, in the embodiment of the present invention, the arrow symbol represents the direction of solar illumination, 101 is a first glass layer, 102 is a first encapsulated layer, 103 is a bifacial solar cell, 106 is a gap between the bifacial solar cells, 104 is a second encapsulated layer, and 105 is a second glass layer, wherein one side of the first glass layer includes embossing having a surface angle in the range of 1 to 45 degrees, and the surface of the embossing is coated with a light reflective coating, such as silver with a thickness of about 200 nm.

As shown in FIG. 1A, the first encapsulated layer directly contacts the embossing of the first glass layer. If the incident light passes through the gap, it can be reflected to the back side of the bifacial solar cell by the light reflective coating on the embossing so that the bifacial solar cell absorbs the light and produces electricity.

As shown in FIG. 1B, the first encapsulated layer does not directly contact the embossing of the first glass layer, but contacts the other flat surface of the first glass layer. After the incident light passes through the gap, it passes through the first glass layer. Then the light can be reflected to the back side of the bifacial solar cell by the light reflective coating on the embossing so that the bifacial solar cell absorbs the light and produces electricity.

In one embodiment of the present invention, the first or the second encapsulated layer is made of ethylene vinyl acetate or polyvinyl butyral.

In one embodiment of the present invention, the glass layer is tempered glass having a compressive strength of about 120 MPa to about 300 MPa, preferably about 150 MPa to about 250 MPa, a bending strength of about 120 MPa to about 300 MPa, preferably about 150 MPa to about 250 MPa, and a tensile strength of about 90 MPa to about 180 MPa, preferably about 100 MPa to about 150 Mpa.

In one embodiment of the present invention, between the first glass layer and the first encapsulated layer there is an insulation layer. The material of the insulation layer comprises SiO₂ or SiN_{X}. Since the embossing has the metal material of the light reflective coating on it, if the metal material contacts the solar cell, it could result in electricity leakage. Thus, it is preferable to add an insulation layer to the solar cell module.

In one embodiment of the present invention, each of the first and second encapsulated layers has a thickness of about 0.3 mm to 0.9 mm, preferably about 0.4 mm to 0.8 mm. If the above-mentioned insulation layer is present between the first glass layer and the first encapsulated layer, the insulation layer has a thickness of about 30 nm to 120 nm, preferably about 40 nm to 100 nm.

One or more embodiments of the subject invention are illustrated in the following descriptions. Other features, objects and advantages of the subject invention will be easily understood from these descriptions and the claims.

### EXAMPLE

In this example, a tailor-made engraved roller was employed to form honeycomb embossing on tempered glass. The surface angle of the embossing was in the range of 1 to 45 degrees and the largest depth was measured as 66 μm. Physical vapor deposition technique was employed to form a light reflective coating made of aluminum material having a thickness of about 80 nm on the embossing, and to form an insulation layer of SiO₂ having a thickness of about 30 nm. An encapsulated layer made of EVA was formed on the insulation layer by using a lamination process. Sixty bifacial solar cells were attached to the encapsulated layer by the lamination, wherein the space between the solar cells was about 2 mm. Another encapsulated layer made of EVA was formed on the bifacial solar cells by the lamination. Then, tempered glass was formed on the encapsulated layer by the lamination. Finally, the solar cell module of the present invention was prepared. The power of the solar cell module of the present invention was measured as 260 W.

In a solar cell module using tempered glass without the embossing and without a light reflective coating formed thereon as a back sheet, but in which the method of using the bifacial solar cells to form a solar cell module otherwise remained the same (its structure: tempered glass/EVA/bifacial solar cells/EVA/tempered glass), the power of such solar cell module was measured as 245 W.

Thus, in comparison with the solar cell module without the embossing and without a light reflective coating, the solar cell module obtained from the present invention was found to generate 6% more power.

Although illustrative embodiments have been described in reference to the subject invention, it should be understood that features which can be easily modified or adjusted by a person of ordinary skill in the art would fall into the scope of the specification of the subject application and the claims attached hereto.

What is claimed is:

1. A solar cell module, the module comprising:
a first glass layer, wherein one side of the glass layer comprises embossing, the surface angle of the embossing is in the range of 1 to 45 degrees, and the surface of the embossing comprises a light reflective coating;
a first encapsulated layer located above the first glass layer;
a bifacial solar cell located above the first encapsulated layer;
a second encapsulated layer located above the bifacial solar cell; and
a second glass layer located above the second encapsulated layer.

2. The solar cell module according to claim 1, wherein the first glass layer, the second glass layer or both are tempered glass.

3. The solar cell module according to claim 1, wherein the first glass layer or the second glass layer has a thickness from about 0.5 mm to about 3 mm.

4. The solar cell module according to claim 1, wherein the first encapsulated layer comprises ethylene vinyl acetate, polyvinyl butyral, a thin-film ionic polymer, or silicone resin.

5. The solar cell module according to claim 1, wherein the second encapsulated layer comprises ethylene vinyl acetate, polyvinyl butyral, a thin-film ionic polymer, or silicone resin.

6. The solar cell module according to claim 1, wherein the material of the light reflective coating is aluminum or silver.

7. The solar cell module according to claim 6, wherein the light reflective coating has a thickness of 40 to 200 nm.

8. The solar cell module according to claim 1, further comprising an insulation layer between the first glass layer and the bifacial solar cell.

9. The solar cell module according to claim 8, wherein the material of the insulation layer comprises SiO₂ or SiN_{X}.

10. The solar cell module according to claim 2, wherein the first glass layer or the second glass layer has a thickness from about 0.5 mm to about 3 mm.

11. The solar cell module according to claim 2, wherein the first encapsulated layer comprises ethylene vinyl acetate, polyvinyl butyral, a thin-film ionic polymer, or silicone resin.

12. The solar cell module according to claim 2, wherein the second encapsulated layer comprises ethylene vinyl acetate, polyvinyl butyral, a thin-film ionic polymer, or silicone resin.

13. The solar cell module according to claim 2, wherein the material of the light reflective coating is aluminum or silver.

14. The solar cell module according to claim 13, wherein the light reflective coating has a thickness of 40 to 200 nm.

15. The solar cell module according to claim 2, further comprising an insulation layer between the first glass layer and the bifacial solar cell.

16. The solar cell module according to claim 15, wherein the material of the insulation layer comprises SiO₂ or SiN_{X}.
